(19) United States
(12) Patent Application Publication
(10) Pub. No.: US 2014/0217470 A1
(43) Pub. Date: Aug. 7, 2014

(54) Ga2O3 SEMICONDUCTOR ELEMENT

(71) Applicants: KYOTO UNIVERSITY, KYOTO-SHI (JP); NATIONAL INSTITUTE OF INFORMATION AND COMMUNICATION TECHNOLOGY, TOKYO (JP)

(72) Inventors: Kohei Sasaki, Tokyo (JP); Masataka Higashiwaki, Tokyo (JP); Shizuo Fujita, Kyoto-shi (JP)

(73) Assignees: TAMURA CORPORATION, Tokyo (JP); KYOTO UNIVERSITY, Kyoto-shi, Kyoto (JP); NATIONAL INSTITUTE OF INFORMATION AND COMMUNICATIONS TECHNOLOGY, Tokyo (JP)

(21) Appl. No.: 14/343,652

(22) PCT Filed: Sep. 7, 2012
(86) PCT No.: PCT/JP2012/072899

§ 371 Date: Mar. 7, 2014

(30) Foreign Application Priority Data
Sep. 8, 2011 (JP) 2011-196437

(51) Int. Cl. H01L 29/78

(52) U.S. Cl. CPC H01L 29/78
USPC 257/192

(57) ABSTRACT

Provided is a high-quality Ga₂O₃ semiconductor element. Provided is, as one embodiment of the present invention, a Ga₂O₃ MISFET (10), which includes: an n-type α-(AlₓGa₁₋ₓ)₂O₃ single crystal film (3), which is formed on an α-Al₂O₃ substrate (2) directly or with other layer therebetween, and is composed of an α-(AlₓGa₁₋ₓ)₂O₃ single crystal (0≦x<1); a source electrode (12) and a drain electrode (13), which are formed on the n-type α-(AlₓGa₁₋ₓ)₂O₃ single crystal film (3); contact regions (14, 15), which are formed in the n-type α-(AlₓGa₁₋ₓ)₂O₃ single crystal film (3), and are connected to the source electrode (12) and the drain electrode (13), respectively; and a gate electrode (11), which is formed on a region between the contact region (14) and the contact region (15) in the n-type α-(AlₓGa₁₋ₓ)₂O₃ single crystal film (3) with the gate insulating film (16) therebetween.

### TECHNICAL FIELD

The invention relates to a Ga₂O₃-based semiconductor element.

### BACKGROUND ART

A β-Ga₂O₃-based semiconductor element using a β-Ga₂O₃ crystal film formed on an α-Al₂O₃ (sapphire) substrate is known (see, e.g., NPL 1).

### CITATION LIST

### Non Patent Literature

[NPL 1]

K. Matsuzaki et al. Appl. Phys. Lett. 88, 092106, 2006.

### SUMMARY OF INVENTION

### Technical Problem

However, it is difficult to grow a monoclinic β-Ga₂O₃ crystal film on an α-Al₂O₃ substrate having a corundum structure and it is not possible to obtain a high-quality β-Ga₂O₃ crystal film. Thus, it is difficult to form a high-quality Ga₂O₃-based semiconductor element by using a β-Ga₂O₃ crystal film grown on an α-Al₂O₃ substrate.

It is an object of the invention to provide a high-quality Ga₂O₃-based semiconductor element.

### Solution to Problem

According to one embodiment of the invention, a Ga₂O₃-based semiconductor element as defined in [1] to [4] below is provided so as to achieve the above object.

[1] A Ga₂O₃-based semiconductor element, comprising:
an α-(AlₓGa₁₋ₓ)₂O₃ single crystal film that comprises an α-(AlₓGa₁₋ₓ)₂O₃ single crystal (0≦x<1) and is formed on an α-Al₂O₃ substrate directly or via an other layer;
a source electrode and a drain electrode that are formed on the α-(AlₓGa₁₋ₓ)₂O₃ single crystal film;
a first contact region and a second contact region that are formed in the α-(AlₓGa₁₋ₓ)₂O₃ single crystal film and are connected to the source electrode and the drain electrode, respectively; and
a gate electrode that is formed via a gate insulating film on a region between the first contact region and the second contact region of the α-(AlₓGa₁₋ₓ)₂O₃ single crystal film.

[2] The Ga₂O₃-based semiconductor element according to [1], wherein the α-(AlₓGa₁₋ₓ)₂O₃ single crystal film, the first contact region and the second contact region are of an n-type, and
wherein the semiconductor element further comprises a p-type or high-resistance body region formed in the α-(AlₓGa₁₋ₓ)₂O₃ single crystal film so as to surround the first contact region.

[3] The Ga₂O₃-based semiconductor element according to [1], wherein the α-(AlₓGa₁₋ₓ)₂O₃ single crystal film comprises a high resistance region including no dopants, and
wherein the first contact region and the second contact region are of an n-type.

[4] The Ga₂O₃-based semiconductor element according to [1], wherein the α-(AlₓGa₁₋ₓ)₂O₃ single crystal film is of a p-type, and
wherein the first contact region and the second contact region are of an n-type.

### Advantageous Effects of Invention

According to an embodiment of the invention, a high-quality Ga₂O₃-based semiconductor element can be provided.

### BRIEF DESCRIPTION OF DRAWINGS

[FIG. 1]

FIG. 1 is a cross sectional view showing a Ga₂O₃-based MISFET in a first embodiment.

[FIG. 2]

FIG. 2 is a structural diagram illustrating an example of an MBE system used for forming the α-(AlₓGa₁₋ₓ)₂O₃ single crystal film.

[FIG. 3]

FIG. 3 is a cross sectional view showing a Ga₂O₃-based MISFET in a second embodiment.

[FIG. 4]

FIG. 4 is a cross sectional view showing a Ga₂O₃-based MISFET in a third embodiment.

### DESCRIPTION OF EMBODIMENTS

According to the present embodiment, it is possible to form a high-quality α-(AlₓGa₁₋ₓ)₂O₃ single crystal film on an α-Al₂O₃ substrate by homoepitaxial growth and use of such a high-quality α-(AlₓGa₁₋ₓ)₂O₃ single crystal film allows a high-quality Ga₂O₃-based semiconductor element to be formed. Examples of embodiments thereof will be described in detail below.

### First Embodiment

A Ga₂O₃-based MISFET (Metal Insulator Semiconductor Field Effect Transistor) having a planar gate structure will be described as the Ga₂O₃-based semiconductor element in the first embodiment.

### (Structure of Ga₂O₃-Based Semiconductor Element)

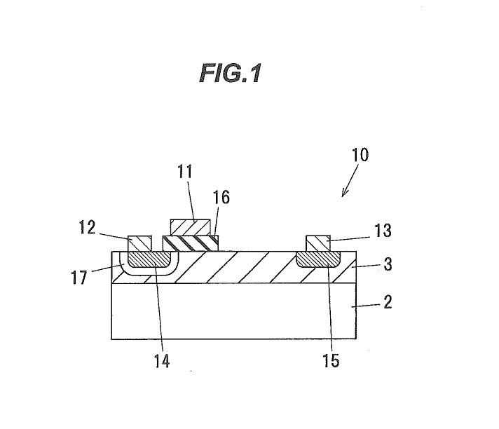

FIG. 1 is a cross sectional view showing a Ga₂O₃-based MISFET in the first embodiment. A Ga₂O₃-based MISFET 10 includes an n-type α-(AlₓGa₁₋ₓ)₂O₃ single crystal film 3 formed on an α-Al₂O₃ substrate 2, a source electrode 12 and a drain electrode 13 which are formed on the n-type α-(AlₓGa₁₋ₓ)₂O₃ single crystal film 3, contact regions 14 and 15 which are formed in the n-type α-(AlₓGa₁₋ₓ)₂O₃ single crystal film 3 respectively under the source electrode 12 and the drain electrode 13, a gate electrode 11 which is formed on the n-type α-(AlₓGa₁₋ₓ)₂O₃ single crystal film 3 via a gate insulating film 16 above the region between the contact region 14 and the contact region 15, and a body region 17 surrounding the contact region 14.

The gate electrode 11 is located above the body region 17 in a region between the source electrode 12 and the drain electrode 13.

The Ga₂O₃-based MISFET 10 functions as a normally-off transistor. When voltage of more than the threshold is applied to the gate electrode 11, a channel is formed in a region of the body region 17 under the gate electrode 11 and a current thus flows from the source electrode 12 to the drain electrode 13.

The n-type α-(AlₓGa₁₋ₓ)₂O₃ single crystal film 3 is an α-(AlₓGa₁₋ₓ)₂O₃ (0≦x<1) single crystal film formed on the α-Al₂O₃ substrate 2. The n-type α-(AlₓGa₁₋ₓ)₂O₃ single crystal film 3 includes an n-type dopant such as Sn, Ti, Zr, Hf, V, Nb, Ta, Mo, W, Ru, Rh, Ir, C, Si, Ge, Pb, Mn, As, Sb, Bi, F, Cl, Br and I. The n-type α-(AlₓGa₁₋ₓ)₂O₃ single crystal film 3 includes an n-type dopant at a concentration of, e.g, not less than 1×10¹⁵/cm³ and not more than 1×10¹⁹cm³. In addition, the thickness of the n-type α-(AlₓGa₁₋ₓ)₂O₃ single crystal film 3 is, e.g., 0.01 to 10 μm.

Here, another film such as an undoped β-Ga₂O₃ single crystal film may be formed between the α-Al₂O₃ substrate 2 and the n-type α-(AlₓGa₁₋ₓ)₂O₃ single crystal film 3. In this case, the undoped P-Ga₂O₃ single crystal film is formed on the α-Al₂O₃ substrate 2 by epitaxial growth and the n-type (AlₓGa₁₋ₓ)₂O₃ single crystal film 3 is formed on the undoped β-Ga₂O₃ single crystal film by epitaxial growth.

The gate electrode 11, the source electrode 12 and the drain electrode 13 are formed of, e.g., a metal such as Au, Al, Ti, Sn, Ge, In, Ni, Co, Pt, W, Mo, Cr, Cu and Pb, an alloy containing two or more of such metals, or a conductive compound such as ITO. In addition, the structure thereof may be a two-layer structure composed of two different metals, e.g., Al/Ti, Au/Ni or Au/Co.

The gate insulating film 16 is formed of a material such as SiO₂, AlN, SiN or α-(Al_{y}Ga_{1-y})₂O₃ (0<y<1). Of those, α-(Al_{y}Ga_{1-y})₂O₃ has the same crystal structure as the α-Al₂O₃ crystal and thus allows a good semiconductor/insulating film interface with less interface states to be formed, resulting in better gate characteristics than when using other insulating films.

The contact regions 14 and 15 are regions having a high n-type dopant concentration formed in the n-type α-(AlₓGa₁₋ₓ)₂O₃ single crystal film 3 and are respectively connected to the source electrode 12 and the drain electrode 13. The n-type dopant included in the contact regions 14 and 15 and that included in the n-type α-(AlₓGa₁₋ₓ)₂O₃ single crystal film 3 may be either the same or different. The contact regions 14 and 15 include the n-type dopant at a concentration of, e.g., not less than 1×10¹⁸/cm³ and not more than 5×10¹⁹cm³.

In addition, the n-type dopant concentration in the contact region 15 may be the same as that in the n-type α-(AlₓGa₁₋ₓ)₂O₃ single crystal film 3. In other words, a region of the n-type α-(AlₓGa₁₋ₓ)₂O₃ single crystal film 3 into which the n-type dopant is not additionally implanted can be used as the contact region 15.

The body region 17 includes a p-type dopant such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Tl, Pb, N or P. The body region 17 is a p-type region or a high resistance region which behaves like i-type due to charge compensation.

### (Method of Manufacturing Ga₂O₃-Based MISFET)

A process using the Molecular Beam Epitaxy (MBE) will be described below as an example of the method of manufacturing the α-(AlₓGa₁₋ₓ)₂O₃ single crystal film. The MBE is a crystal growth method in which a single or compound solid is heated in an evaporation source called cell and vapor generated by heat is supplied as a molecular beam onto the surface of the substrate.

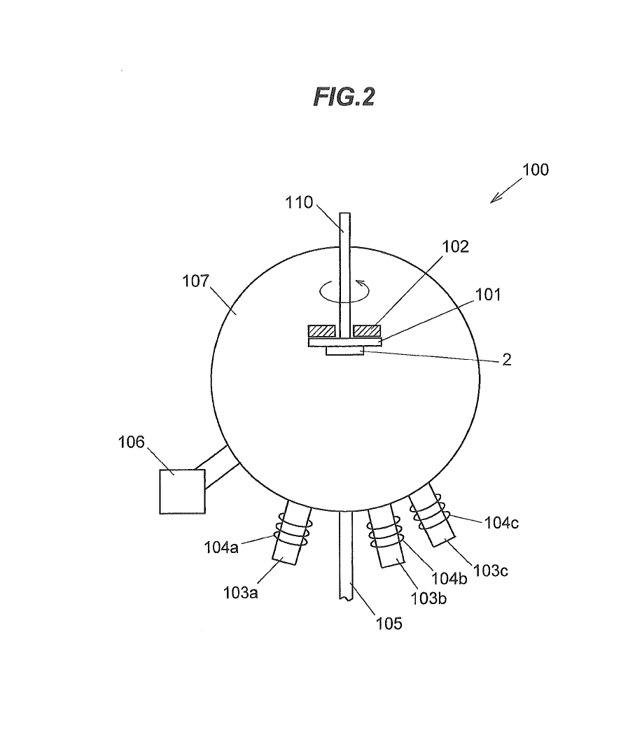

FIG. 2 is a structural diagram illustrating an example of an MBE system used for forming the α-(AlₓGa₁₋ₓ)₂O₃ single crystal film. The MBE system 100 is provided with a vacuum chamber 107, a substrate holder 101 supported in the vacuum chamber 107 to hold the α-Al₂O₃ substrate 2, heating devices 102 held on the substrate holder 101 to heat the α-Al₂O₃ substrate 2, plural cells 103 (103a, 103b, 103c) each provided for each atom or molecule constituting a thin film, heaters 104 (104a, 104b, 104c) for hearing the plural cells 103, a gas supply pipe 105 for supplying oxygen-based gas into the vacuum chamber 107, and a vacuum pump 106 for exhausting the air in the vacuum chamber 107. It is configured that the substrate holder 101 can be rotated by a non-illustrated motor via a shaft 110.

A Ga raw material of the α-(AlₓGa₁₋ₓ)₂O₃ single crystal film, such as Ga powder, is loaded in the first cell 103a. The Ga powder desirably has a purity of not less than 6N. Powder of an n-type dopant raw material to be doped as a donor is loaded in the second cell 103b. An Al raw material of the α-(AlₓGa₁₋ₓ)₂O₃ single crystal film, such as Al powder, is loaded in the third cell 103c. A shutter is provided at an opening of each of the first cell 103a, the second cell 103b and the third cell 103c.

Firstly, the α-Al₂O₃ substrate 2 is attached to the substrate holder 101 of the MBE system 100. Next, the vacuum pump 106 is activated to reduce atmospheric pressure in the vacuum chamber 107 to about 10⁻¹⁰ Torr. Then, the α-Al₂O₃ substrate 2 is heated by the heating devices 102. Here, radiation heat of heat source such as graphite heater of the heating device 102 is thermally transferred to the α-Al₂O₃ substrate 2 via the substrate holder 101 and the α-Al₂O₃ substrate 2 is thereby heated.

After the α-Al₂O₃ substrate 2 is heated to a predetermined temperature, oxygen-based gas is supplied into the vacuum chamber 107 through the gas supply pipe 105.

After a period of time required for stabilization of gas pressure in the vacuum chamber 107 (e.g., after 5 minutes) since the oxygen-based gas was supplied into the vacuum chamber 107, the first cell 103a, the second cell 103b and the second cell 103c are respectively heated by the first heater 104a, the second heater 104b and the third heater 104c while rotating the substrate holder 101 so that Ga, Al and n-type dopant are evaporated and are radiated as molecular beam onto the surface of the α-Al₂O₃ substrate 2.

As such, the α-(AlₓGa₁₋ₓ)₂O₃ single crystal is epitaxially grown on the main surface of the α-Al₂O₃ substrate 2 while being doped with the n-type dopant such as Sn and the n-type α-(AlₓGa₁₋ₓ)₂O₃ single crystal film 3 is thereby formed. It should be noted that as the n-type dopant other than Sn, it is possible to use Ti, Zr, Hf, V, Nb, Ta, Mo, W, Ru, Rh, Ir, C, Si, Ge, Pb, Mn, As, Sb and Bi, etc., for substituting Ga or Al site and it is possible to use F, Cl, Br and I, etc., for substituting oxygen site. The addition concentration of the n-type dopant can be controlled by temperature of the second cell 103b during film formation.

Alternatively, the n-type ct-(AlₓGa₁₋ₓ)₂O₃ single crystal film 3 may be formed by the PLD (Pulsed Laser Deposition) or the CVD (Chemical Vapor Deposition) etc.

After forming the n-type α-(AlₓGa₁₋ₓ)₂O₃ single crystal film 3, the body region 17 is formed by ion-implanting a p-type dopant such as Mg into the n-type α-(AlₓGa₁₋ₓ)₂O₃ single crystal film 3. It should be noted that the ion to be implanted is not limited to Mg and, when substituting, e.g., Ga or Al site, it is possible to use H, Li, Na, K, Rb, Cs, Fr, Be, Ca, Sr, Ba, Ra, Mn, Fe, Co, Ni, Pd, Cu, Ag, Au, Zn, Cd, Hg, Tl or Pb. In addition, it is possible to use N or P when substituting oxygen site. After implanting the p-type dopant, damage caused by implantation is repaired by performing annealing treatment.

It should be noted that the method of forming the body region 17 is not limited to ion implantation and thermal diffusion process may be used. In this case, after metal such as Mg is brought into contact with the n-type α-(AlₓGa₁₋ₓ)₂O₃ single crystal film 3 in a region for the body region 17 to be formed, heat treatment is performed to diffuse a dopant such as Mg into the n-type α-(AlₓGa₁₋ₓ)₂O₃ single crystal film 3.

Next, the contact regions 14 and 15 are formed by ion-planting the n-type dopant into the body region 17 of the n-type α-(AlₓGa₁₋ₓ)₂O₃ single crystal film 3. It should be noted that the ion to be implanted is not limited to Sn and, when substituting, e.g., Ga or Al site, it is possible to use Ti, Zr, Hf, V, Nb, Ta, Mo, W, Ru, Rh, Ir, C, Si, Ge, Pb, Mn, As, Sb or Bi. In addition, it is possible to use F, Cl, Br or I when substituting oxygen site.

The implantation concentration is, e.g., not less than 1×10¹⁸/cm³ and not more than 5×10¹⁹cm³. The implantation depth is not less than 30 nm. After implantation, the surface of the implanted region is etched about 10 nm by hydrofluoric acid. Sulfuric acid, nitric acid or hydrochloric acid may be used for the etching. After that, implantation damage is repaired by performing annealing treatment in a nitrogen atmosphere at not less than 800° C. for not less than 30 minutes. In case of performing the annealing treatment in an oxygen atmosphere, treatment temperature is not less than 800° C. and not more than 950° C. and treatment time is not less than 30 minutes.

It should be noted that the method of forming the contact regions 14 and 15 is not limited to ion implantation and thermal diffusion process may be used. In this case, after metal such as Sn is brought into contact with the n-type α-(AlₓGa₁₋ₓ)₂O₃ single crystal film 3 in a region for the contact regions 14 and 15 to be formed, heat treatment is performed to diffuse a dopant such as Sn into the n-type α-(AlₓGa₁₋ₓ)₂O₃ single crystal film 3.

After that, the gate insulating film 16, the gate electrode 11, the source electrode 12 and the drain electrode 13 are formed.

### Second Embodiment

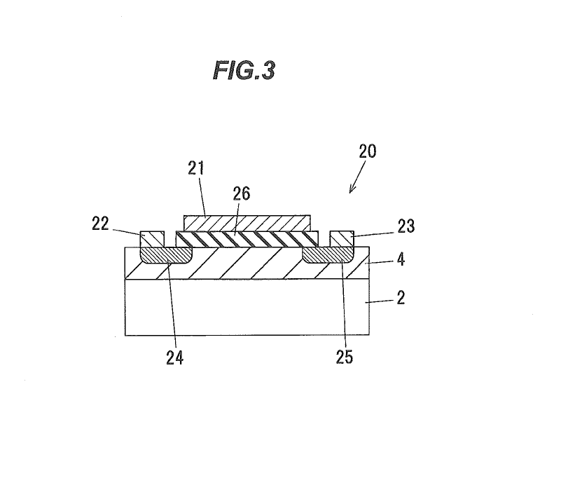

FIG. 3 is a cross sectional view showing a Ga₂O₃-based MISFET in the second embodiment. A Ga₂O₃-based MISFET 20 includes an undoped α-(AlₓGa₁₋ₓ)₂O₃ single crystal film 4 formed on the α-Al₂O₃ substrate 2, a source electrode 22 and a drain electrode 23 which are formed on the undoped α-(AlₓGa₁₋ₓ)₂O₃ single crystal film 4, contact regions 24 and 25 which are formed in the undoped α-(AlₓGa₁₋ₓ)₂O₃ single crystal film 4 respectively under the source electrode 22 and the drain electrode 23, and a gate electrode 21 which is formed on the undoped α-(AlₓGa₁₋ₓ)₂O₃ single crystal film 4 via a gate insulating film 26 above the region between the contact region 24 and the contact region 25.

The Ga₂O₃-based MISFET 20 functions as a normally-off transistor. When voltage of more than the threshold is applied to the gate electrode 21, a channel is formed in a region of the undoped α-(AlₓGa₁₋ₓ)₂O₃ single crystal film 4 under the gate electrode 21 and a current thus flows from the source electrode 22 to the drain electrode 23.

The gate electrode 21, the source electrode 22, the drain electrode 23 and the gate insulating film 26 are respectively formed of the same materials as the gate electrode 11, the source electrode 12, the drain electrode 13 and the gate insulating film 16 in the first embodiment.

The undoped α-(AlₓGa₁₋ₓ)₂O₃ single crystal film 4 is a high-resistance α-(AlₓGa₁₋ₓ)₂O₃ (0≦x<1) single crystal film which does not include a dopant. Although there may be a case where conductivity thereof is low due to crystal defects, etc., electric resistance thereof is sufficiently high and a current never flows from the source electrode 22 to the drain electrode 23 unless voltage is applied to the gate electrode 21. The thickness of the undoped α-(AlₓGa₁₋ₓ)₂O₃ single crystal film 4 is, e.g., 0.01 to 10 μm.

The method of forming the undoped α-(AlₓGa₁₋ₓ)₂O₃ single crystal film 4 is, e.g., based on the method of forming the n-type α-(AlₓGa₁₋ₓ)₂O₃ single crystal film 3 in the first embodiment where the process of implanting the n-type dopant is eliminated.

The contact regions 24 and 25 are regions having a high n-type dopant concentration formed in the undoped α-(AlₓGa₁₋ₓ)₂O₃ single crystal film 4 and are respectively connected to the source electrode 22 and the drain electrode 23. The contact regions 24 and 25 include the n-type dopant at a concentration of, e.g., not less than 1×10¹⁸/cm³ and not more than 5×10¹⁹cm³.

### Third Embodiment

The third embodiment is different from the second embodiment in that a p-type α-(AlₓGa₁₋ₓ)₂O₃ single crystal film is formed instead of the undoped α-(AlₓGa₁₋ₓ)₂O₃ single crystal film 4. The explanations for the same features as the first embodiment will be omitted or simplified.

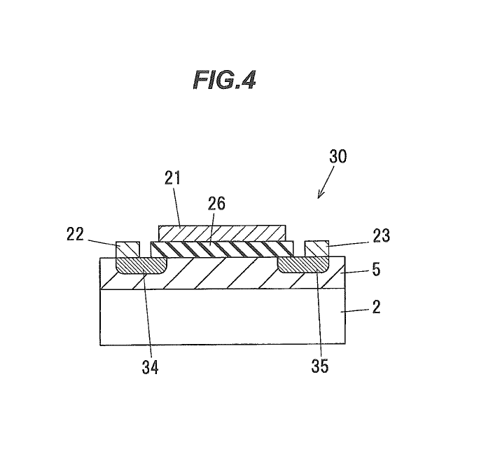

FIG. 4 is a cross sectional view showing a Ga₂O₃-based MISFET in the third embodiment. A Ga₂O₃-based MISFET 30 includes a p-type α-(AlₓGa₁₋ₓ)₂O₃ single crystal film 5 formed on the α-Al₂O₃ substrate 2, the source electrode 22 and the drain electrode 23 which are formed on the p-type α-(AlₓGa₁₋ₓ)₂O₃ single crystal film 5, contact regions 34 and 35 which are formed in the p-type α-(AlₓGa₁₋ₓ)₂O₃ single crystal film 5 respectively under the source electrode 22 and the drain electrode 23, and the gate electrode 21 which is formed on the p-type α-(AlₓGa₁₋ₓ)₂O₃ single crystal film 5 via the gate insulating film 26 above the region between the contact region 34 and the contact region 35.

The Ga₂O₃-based MISFET 30 functions as a normally-off transistor. When voltage of more than the threshold is applied to the gate electrode 21, a channel is formed in a region of the p-type α-(AlₓGa₁₋ₓ)₂O₃ single crystal film 5 under the gate electrode 21 and a current thus flows from the source electrode 22 to the drain electrode 23.

The p-type α-(AlₓGa₁₋ₓ)₂O₃ single crystal film 5 is an α-(AlₓGa₁₋ₓ)₂O₃ (0≦x<1) single crystal film which includes a p-type dopant such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Tl, Pb, N or P. The p-type α-(AlₓGa₁₋ₓ)₂O₃ single crystal film 5 includes the p-type dopant at a concentration of, e.g., not less than 1×10¹⁵/cm³ and not more than 1×10¹⁹cm³. In addition, the thickness of the p-type α-(AlₓGa₁₋ₓ)₂O₃ single crystal film 5 is, e.g., 0.01 to 10 μm.

The method of forming the p-type α-(AlₓGa₁₋ₓ)₂O₃ single crystal film 5 is, e.g., based on the method of forming the n-type α-(AlₓGa₁₋ₓ)₂O₃ single crystal film 3 in the first embodiment where the process of implanting the n-type dopant is replaced with a process of implanting the p-type dopant.

The contact regions 34 and 35 are regions having a high n-type dopant concentration formed in the p-type α-(AlₓGa₁₋ₓ)₂O₃ single crystal film 5 and are respectively connected to the source electrode 22 and the drain electrode 23. The contact regions 34 and 35 include the n-type dopant at a concentration of, e.g., not less than 1×10¹⁸/cm³ and not more than 5×10¹⁹cm³.

### Effects of the Embodiments

According to the present embodiment, it is possible to form high-quality α-(AlₓGa₁₋ₓ)₂O₃ single crystal films by homoepitaxial growth and use of such α-(AlₓGa₁₋ₓ)₂O₃ single crystal films allows high-quality Ga₂O₃-based semiconductor elements to be formed. In addition, these Ga₂O₃-based semiconductor elements have excellent performance since a high-quality α-(AlₓGa₁₋ₓ)₂O₃ single crystal film is used as a channel layer.

It should be noted that the invention is not intended to be limited to the above-mentioned embodiments, and the various kinds of modifications can be implemented without departing from the gist of the invention. For example, the Ga₂O₃-based semiconductor element has been described as the n-type semiconductor element in the embodiments but may be a p-type semiconductor element. In this case, the conductivity type (n-type or p-type) of each member is all inverted. In addition, constituent elements of the above-mentioned embodiments can be arbitrarily combined without departing from the gist of the invention.

Although the embodiments of the invention have been described above, the invention according to claims is not to be limited to the above-mentioned embodiments. Further, it should be noted that all combinations of the features described in the embodiments are not necessary to solve the problem of the invention.

### INDUSTRIAL APPLICABILITY

A high-quality Ga₂O₃-based semiconductor element is provided.

### REFERENCE SIGNS LIST

2: α-Al₂O₃ substrate
3: n-type α-(AlₓGa₁₋ₓ)₂O₃ single crystal film
4: undoped α-(AlₓGa₁₋ₓ)₂O₃ single crystal film
5: p-type α-(AlₓGa₁₋ₓ)₂O₃ single crystal film
10, 20, 30: Ga₂O₃-based MISFET
11, 21: gate electrode
12, 22: source electrode
13, 23: drain electrode
14, 15, 24, 25, 34, 35: contact region
16, 26: gate insulating film
17: body region

1. A Ga₂O₃-based semiconductor element, comprising:
an α-(AlₓGa₁₋ₓ)₂O₃ single crystal film that comprises an α-(AlₓGa₁₋ₓ)₂O₃ single crystal (0≦x<1) and is formed on an α-Al₂O₃ substrate directly or via an other layer;
a source electrode and a drain electrode that are formed on the α-(AlₓGa₁₋ₓ)₂O₃ single crystal film;
a first contact region and a second contact region that are formed in the α-(AlₓGa₁₋ₓ)₂O₃ single crystal film and are connected to the source electrode and the drain electrode, respectively; and
a gate electrode that is formed via a gate insulating film on a region between the first contact region and the second contact region of the α-(AlₓGa₁₋ₓ)₂O₃ single crystal film.

2. The Ga₂O₃-based semiconductor element according to claim 1, wherein the α-(AlₓGa₁₋ₓ)₂O₃ single crystal film, the first contact region and the second contact region are of an n-type, and
wherein the semiconductor element further comprises a p-type or high-resistance body region formed in the α-(AlₓGa₁₋ₓ)₂O₃ single crystal film so as to surround the first contact region.

3. The Ga₂O₃-based semiconductor element according to claim 1, wherein the α-(AlₓGa₁₋ₓ)₂O₃ single crystal film comprises a high resistance region including no dopants, and
wherein the first contact region and the second contact region are of an n-type.

4. The Ga₂O₃-based semiconductor element according to claim 1, wherein the α-(AlₓGa₁₋ₓ)₂O₃ single crystal film is of a p-type, and wherein the first contact region and the second contact region are of an n-type.
